(19) United States
(12) Patent Application Publication
(10) Pub. No.: US 2015/0046109 A1
(43) Pub. Date: Feb. 12, 2015

(54) BATTERY SYSTEM MAINTENANCE MANAGEMENT SYSTEM AND METHOD

(71) Applicant: HITACHI, LTD., Tokyo (JP)

(72) Inventors: Toshiharu Miwa, Tokyo (JP); Daisuke Katsumata, Tokyo (JP); Chizu Noguchi, Tokyo (JP); Hiroomi Onda, Tokyo (JP)

(21) Appl. No.: 14/395,866

(22) PCT Filed: Apr. 5, 2013
(86) PCT No.: PCT/JP2013/060425

§ 371 Date: Oct. 21, 2014

(30) Foreign Application Priority Data
Apr. 23, 2012 (JP) 2012-097757

(51) Int. Cl. G01R 31/36

(52) U.S. Cl. CPC G01R 31/3682; G01R 31/3606; G01R 31/3651
USPC 702/63

(57) ABSTRACT

Proposed is a method for efficiently indicating the replacement timing of each battery module which is a constituent element of a battery system on the basis of operational results information of the battery system without lowering the operating ratio of the battery system. First, capacity-voltage profile data of the battery module according to manufacturing state and degradation state, capacity-voltage profile data at the time of shipping of the battery module, and most recent capacity-voltage profile data of the battery module are collated to estimate the degradation degree of the battery module of the battery system. Then, based on past charge/discharge results data of the battery module, a future use pattern is estimated. Thereafter, remaining operating life is computed based on the degradation degree, the use pattern of the battery module, and characteristics degradation data. Finally, based on the remaining operating computed for the life battery module, the replacement timing of the individual battery module is indicated.

### TECHNICAL FIELD

The present invention relates to systems and methods for managing the maintenance of a battery system.

### BACKGROUND ART

A lithium ion battery has a far higher energy density than a nickel hydrogen battery. The lithium ion battery also has the characteristic that its memory effect is small. Thus, lithium ion batteries are widely used in portable telephones, notebook computers and other portable devices, and in hybrid vehicles, electric vehicles, and other vehicles.

The lithium ion battery has the characteristics that as the battery is repeatedly charged and discharged, oxidization of electrolytic solution and destruction of a crystal structure occur on the positive electrode side, while precipitation of metallic lithium occurs on the negative electrode side. Because of such characteristics, repetition of charging and discharging decreases the lithium ion battery capacity. If the capacity continues to decrease, the lithium ion battery ceases to be capable of providing necessary electric power to a device as the destination for electric power supply. Accordingly, the lithium ion battery needs to be regularly replaced. Particularly, in a large-scale battery system including a number of lithium ion batteries and capable of providing large amounts of electric power, the efficiency of replacement of a number of lithium ion batteries as they degrade needs to be increased.

As an example of the literature describing the background art of the relevant technical field, Patent Literature 1 is cited. The Abstract portion of the literature reads that “Provided is a vehicular battery diagnosis system capable of presenting a control plan for improving the operating life of a battery mounted on a vehicle, and modifying control information regarding vehicle control.

As another example of the literature describing the background art of the relevant technical field, Patent Literature 2 is cited. The Abstract portion of the literature reads: “The remaining operating life of a battery mounted or to be mounted on an automobile that travels using power from an electric motor is diagnosed with increased adequacy”; and “Operating life information associating the use state of end-of-life batteries with their operating life results (such as the charge characteristics of the end-of-life batteries) is prepared in the form of a database. When the remaining operating life of a battery for diagnosis is diagnosed, an operating life charge voltage variation ΔVmcli is acquired from a region of the database corresponding to the use state of the battery for diagnosis (S140), a diagnosis charge voltage variation ΔVmccu at the time of charging the battery for diagnosis according to a charge sequence is acquired (S170, S180), and a remaining operating life distance Rd or a remaining operating life time Rt of the battery for diagnosis is computed from the relationship between the acquired diagnosis charge voltage variation ΔVmccu and the operating life charge voltage variation ΔVmcli (S190)”.

As another example of the literature describing the background art of the relevant technical field, Patent Literature 3 is cited. The Abstract portion of the literature reads: “When it is determined that the battery 12 has reached the end of its operating life, the use environment of the battery 12 (such as the type of equipped vehicle, area of use, purpose of use, or travel history) is stored in a hard disk drive 54 of the management server 50 as part of an operating life information database, in association with use state information (such as the charge and discharge characteristics of the battery 12, total travel distance Lsum, or total use time Tsum). In this way, the operating life information database can be made more adequate”.

### CITATION LIST

### Patent Literature

Patent Literature 1: JP 2010-119223 A

Patent Literature 2: JP 2011-64571 A

Patent Literature 3: JP 2011-69693 A

### SUMMARY OF INVENTION

### Technical Problem

Patent Literature 1 describes that the vehicle control plan for improving the operating life of the battery is presented based on battery diagnosis information (it is merely described that the battery charge state is calculated based on a current value or a voltage value for diagnosis), and that the vehicle control information is modified in accordance with a control plan selected by the user. Patent Literature 1, however, does not disclose a technology for designating the replacement timing for individual battery.

Patent Literatures 2 and 3 disclose the technology for accurately diagnosing the remaining operating life of a battery mounted or to be mounted on an automobile. However, the literatures do not disclose the technology for designating the replacement timing in accordance with degradation of the individual battery system.

The present invention provides a battery system maintenance management system that determines the replacement timing of an individual battery module.

### Solution to Problem

In order to solve the problem, the present invention provides the following processes (function units):

(1) A degradation degree estimation unit (process) that estimates the degradation degree of each battery module of a battery system by collating capacity-voltage profile data of the battery module according to manufacturing state and degradation state, capacity-voltage profile data at the time of shipping of the battery module, and most recent capacity-voltage profile data of the battery module.
(2) A use pattern estimation unit (process) that estimates a future use pattern based on past charge/discharge results data of the battery module.
(3) A remaining operating life computation unit (process) that computes remaining operating life based on the degradation degree, the use pattern of the battery module, and characteristics degradation data.
(4) A replacement timing indication unit (process) that indicates the replacement timing of the individual battery module based on the remaining operating life computed for the battery module.

### Advantageous Effects of Invention

According to the present invention, the efficiency of battery system maintenance can be increased by determining the replacement timing of each battery module of a battery system. As a result, the operating ratio of the battery system as a whole can be increased.

Other problems, configurations, and effects will become apparent from the following description of embodiments.

### BRIEF DESCRIPTION OF DRAWINGS

FIG. 1 illustrates a configuration example of a system as a whole that uses a battery system.

FIG. 2 schematically illustrates concrete steps for manufacturing a lithium ion battery.

FIG. 3 is a perspective view schematically illustrating a module battery structure of the lithium ion battery.

FIG. 4 illustrates an example of capacity-voltage profile data of charge characteristics data and discharge characteristics data recorded in manufacturing inspection results information.

FIG. 5 illustrates a data example of charge/discharge characteristics data at the time of shipping stored in a manufacturing inspection results database.

FIG. 6 illustrates operational results information.

FIG. 7 illustrates an example of data items of the operational results information.

FIG. 8 illustrates changes in discharge characteristics as a result of battery degradation.

FIG. 9 illustrates an example of the influence of manufacturing conditions on battery degradation, and the influence of operational results on battery degradation.

FIG. 10 illustrates a performance degradation database used for estimating the degradation degree of a battery module.

FIG. 11 illustrates an example of battery module inspection data registered in the performance degradation database.

FIG. 12 illustrates an example of environment results information recorded in an environment results database.

FIG. 13 is a flowchart for describing a process of computing a replacement timing for a battery module of a battery system.

FIG. 14 is a flowchart for describing a process of estimating the battery module degradation degree.

FIG. 15 is a flowchart for describing a pattern matching process for charge/discharge profile data.

FIG. 16 is a flowchart for describing a method of estimating a battery module use pattern based on past operational results.

FIG. 17 is a flowchart for describing a method of estimating a battery module use pattern using past operational results and environment information.

FIG. 18 is a flowchart for describing a process of computing the remaining operating life of a battery module.

FIG. 19 illustrates diagrams for describing a method of computing the remaining operating life of a battery module.

FIG. 20 is a flowchart of a method of computing a battery module replacement timing.

FIG. 21 illustrates an example of the result of the computation of the battery module replacement timing.

### DESCRIPTION OF EMBODIMENTS

In the following, modes of implementation of the present invention will be described with reference to the attached drawings.

### Embodiment 1

### Overall System Configuration

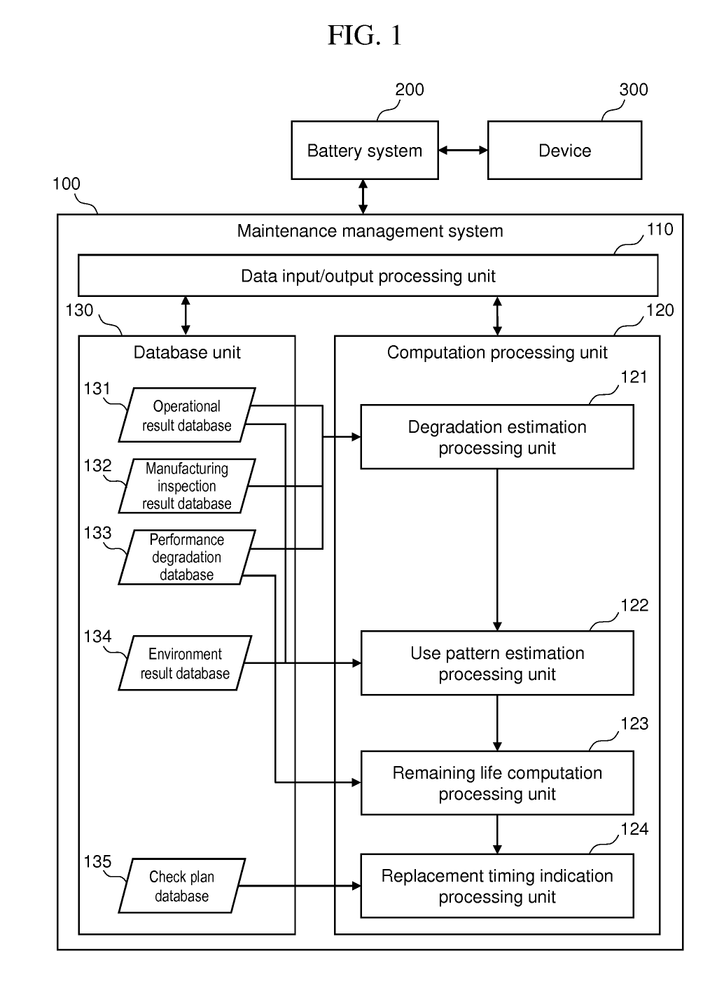

FIG. 1 illustrates the configuration of an overall system that uses a battery system. The overall system includes a battery system 200; a device 300 connected to the battery system 200; and a maintenance management system 100 that manages the replacement timing of a battery module of the battery system 200.

The maintenance management system 100 includes a data input/output processing unit 110; a computation processing unit 120; and a database unit 130.

The computation processing unit 120 may include a computer, for example. In this case, the computation processing unit 120 includes a CPU; a RAM; a ROM; an internal storage device (such as a hard disk); and an input/output interface. A maintenance management function which will be described below is provided through a program read from the internal storage device or the like and executed. When the computation processing unit 120 is realized by a general-purpose computer, a function according to the executed program is provided. To the computation processing unit 120, a display or a printer may be connected.

As the maintenance management functions of the embodiment, the computation processing unit 120 includes a degradation degree estimation processing unit 121; a use pattern estimation processing unit 122; a remaining operating life computation processing unit 123; and a replacement timing indication processing unit 124. The processing units are realized through the execution of the computer program. The details of the process operation executed by each processing unit will be described later.

The database unit 130 includes an operational results database 131; a manufacturing inspection results database 132; a performance degradation database 133; an environment results database 134; and a check plan database 135.

According to the present embodiment, to the maintenance management system 100, a plurality of battery systems 200 are connected. The plurality of battery systems 200 may not be present at one location and may be distributed at a plurality of locations.

Each of the battery systems 200 is connected to the device 300, for example, as the object for the supply of electric power. The device 300 is not limited to a device that uses electricity and may include a device that can generate electricity. For example, the device 300 may include a wind power generation facility. In this case, the battery system 200 may be used as a device for accumulating the generated electricity and also as an auxiliary power supply for stabilizing the electricity output. The device 300 may also include a solar power generation facility. The device 300 may include an information system, such as a server or a data center. When the device 300 is a server, the battery system 200 may be an uninterruptible power supply device (UPS).

### Battery System and its Related Information

According to the present embodiment, the battery systems 200 are configured as assemblies of a plurality of lithium ion battery modules. The battery modules are not limited to lithium ion battery modules. In the case of the present embodiment, each battery module includes a plurality of lithium ion battery cells connected together. The battery module may include a single lithium ion battery cell.

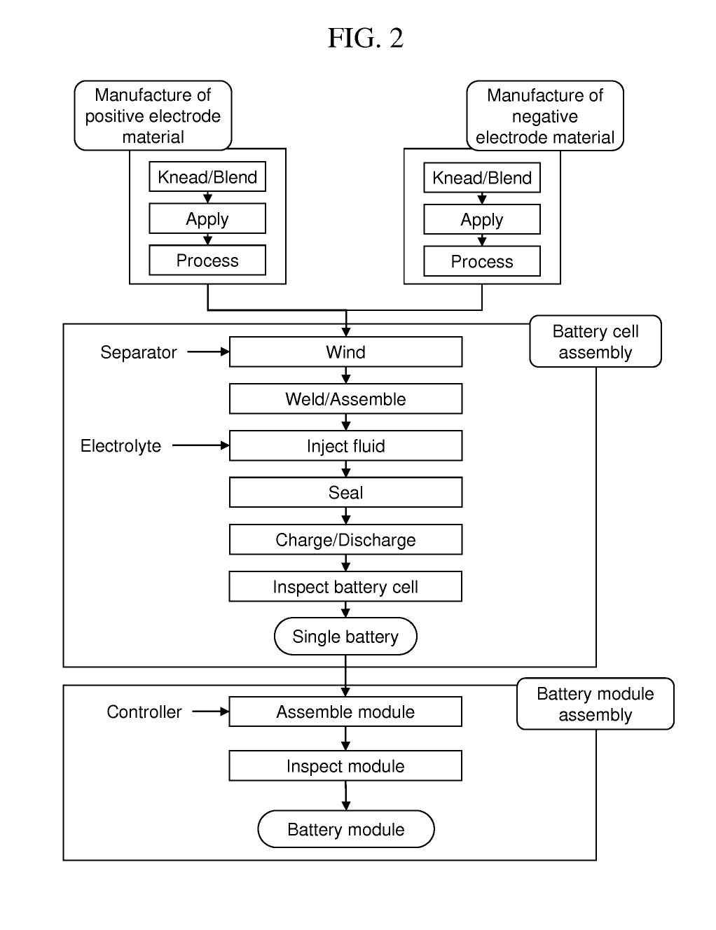

FIG. 2 schematically illustrates concrete steps for manufacturing a lithium ion battery. As illustrated in FIG. 2, the lithium ion battery manufacturing steps include a positive electrode material manufacturing step, a negative electrode material manufacturing step, a battery cell assembly step, and a module battery assembly step.

In the positive electrode material manufacturing step, first, various raw materials for the positive electrode material are kneaded and blended to prepare a slurry material. The slurry material is then applied to metal foil processed into a film. Thereafter, the metal foil with the slurry coating is processed (such as compressed or cut), manufacturing a film of positive electrode material.

In the negative electrode material manufacturing step, the same procedure as for the positive electrode material manufacturing step is performed with the exception that the various materials used as raw material are different from those of the positive electrode material manufacturing step. First, the various materials as raw material for the negative electrode material are kneaded and blended to prepare a slurry material. The slurry material is then applied to a metal foil processed into a film. Thereafter, the metal foil with the slurry coating is processed (such as compressed or cut), manufacturing a film of negative electrode material.

Then, the battery cell assembly step is performed. First, a winding step is performed. In the winding step, necessary sizes of the positive electrode and negative electrode for the battery cell are cut from the films of positive electrode material and negative electrode material. A necessary size of a separator for the battery cell is also cut from a film of separator material used for separating the positive electrode material from the negative electrode material. Thereafter, the separator is sandwiched between the positive electrode and the negative electrode, and they are wound together in a superposed manner. Next, a weld/assembly step is performed. In the weld/assembly step, a group of pairs of the electrodes comprising the positive electrode, the negative electrode, and the separator wound together is assembled and welded. In the next fluid injection step, the group of welded electrode pairs is disposed in a battery can into which electrolytic solution is injected. The battery can is then completely sealed in a sealing step, producing a battery cell. Thereafter, a cell inspection step is performed. The cell inspection step includes a step of repeatedly charging and discharging the lithium ion battery cell produced in the previous step, and inspection of the battery cell performance and reliability (such as the capacity and voltage of the battery cell, the current and voltage during charging or discharging). The battery cell is thus completed and the battery cell assembly step ends.

Next, the battery module assembly step is performed. The battery module assembly step includes a module assembly step and a module inspection step. In the module assembly step, a plurality of battery cells are combined in series, forming a battery module. To the battery module, a battery control unit for charge/discharge control is connected, manufacturing the battery system 200. Then, the module inspection step is performed. In the module inspection step, the assembled battery module is inspected regarding performance and reliability. For example, battery module capacity and voltage, and charge or discharge current and voltage are inspected.

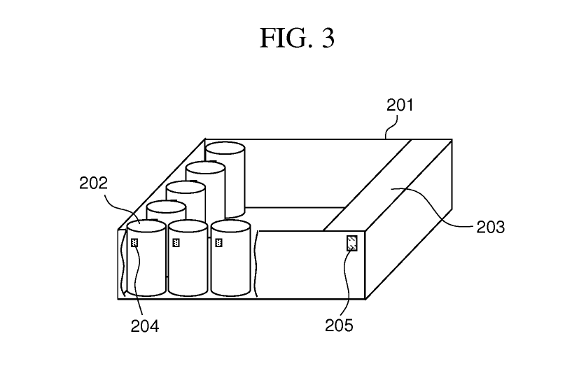

FIG. 3 schematically illustrates the configuration of the manufactured battery module 201. As illustrated in FIG. 3, the battery module 201 includes a plurality of battery cells 202 and a battery control unit 203. The plurality of battery cells 202 are connected in series. Each of the battery cells 202 is provided with a management number mark (such as a bar code) 204 for battery cell identification. The battery module 201 is also provided with a management number mark (such as a bar code) 205 at a position on a housing thereof for battery module identification.

The battery control unit 203 implements creation and management of operational results information (operation history data) regarding charging and discharging, capacity, voltage and the like of the battery cells and the battery module. The battery control unit 203 includes a timer for measuring the time and date of charging and discharging of the battery module 201. The battery control unit 203 acquires operational results data of the battery module at the time of charging and discharging and at the time of stop state, and stores the data in the operational results database 131 of the database unit 130 of the battery system maintenance management system 100. A concrete configuration of the operational results data will be described later.

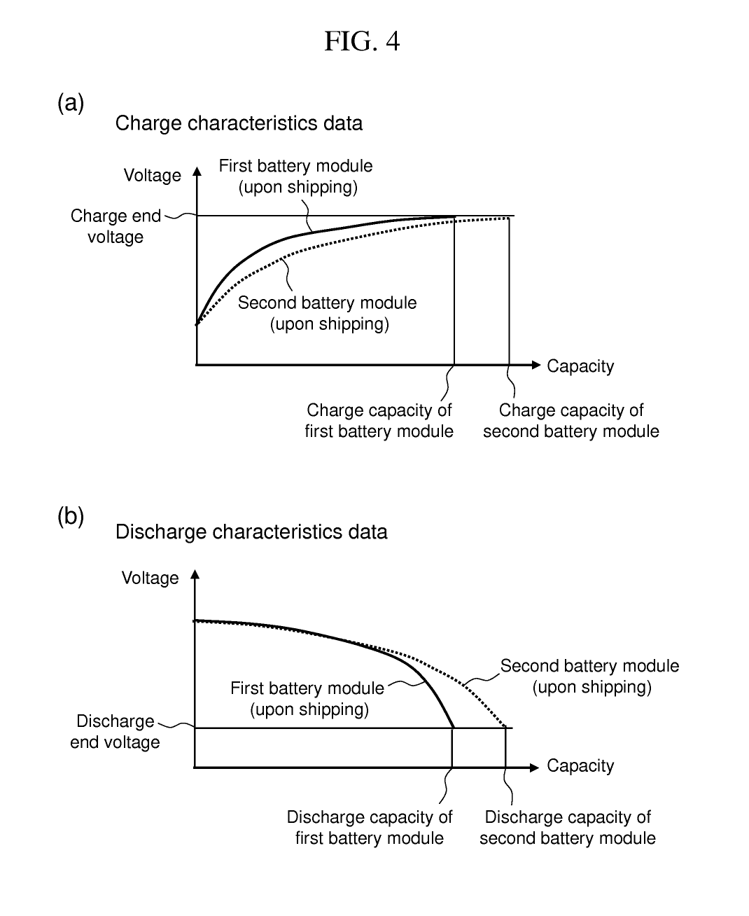

FIG. 4 illustrates charge/discharge characteristics data acquired in the module inspection step performed at the time of manufacture. The data may also be referred to as “capacity-voltage profile data at the time of shipping of the battery module”. FIG. 4(a) is a graph of battery module charge characteristics data. FIG. 4(b) is a graph of battery module discharge characteristics data. The horizontal axis of each graph shows capacity, and the vertical axis shows voltage. In each graph, profile data of a first battery module is indicated by solid line, and profile data of a second battery module is indicated by a dotted line.

During charge inspection, changes in output voltage of the battery module are measured while the battery module is being charged with a predetermined current value. The charge inspection ends when the measured output voltage reaches a charge end voltage. The changes in the relationship between the voltage and capacity that has been measured from the start to end of charging provide charge characteristics data (charge profile data). It should be noted that the “capacity” is not measured data but is computed based on the product of the charging current value and the charge time. The capacity is denoted by the unit Ah. As illustrated in FIG. 4(a), the battery module charge capacity generally has individual differences.

During discharge inspection, changes in output voltage of the battery module are measured while the battery modules is being discharged at a predetermined current value. The discharge inspection ends when the measured output voltage reaches a discharge end voltage. The changes in the relationship between voltage and capacity that has been measured from the start to end of discharging provide discharge characteristics data (discharge profile data). In this case too, the “capacity” is not measured data but is computed based on the product of the discharge current value and the discharge time. The capacity is also denoted by the unit Ah. As illustrated in FIG. 4(b), the battery module discharge capacity generally has individual differences. While in the case of FIG. 4, the charge characteristics data and the discharge characteristics data are substantially similar, in some cases they may be different from each other.

The charge/discharge characteristics data of each battery module obtained as described above are stored in the manufacturing inspection results database 132 of the database unit 130 of the maintenance management system 100 before the battery systems 200 are shipped.

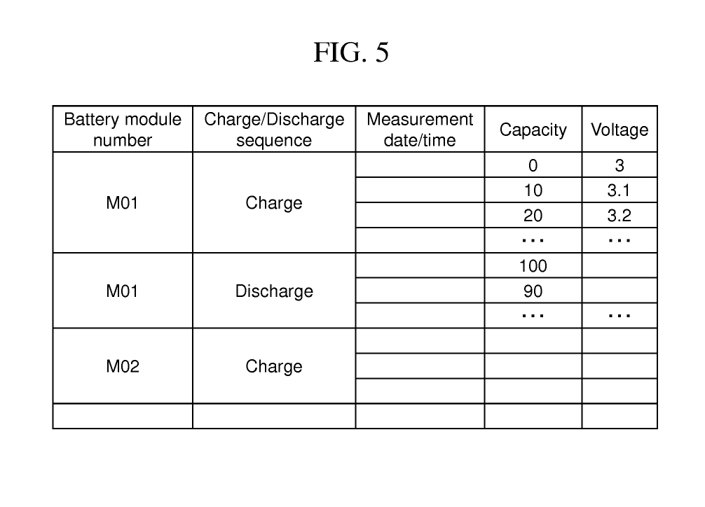

FIG. 5 illustrates an example of data format of the charge/discharge characteristics data stored in the manufacturing inspection results database 132. The charge/discharge characteristics data include items of a battery module number identifying the battery module; data identifying a charge/discharge sequence; date/time of measurement; capacity; and voltage. In the case of FIG. 5, in the “charge” sequence for the battery module number “M01”, for example, when the voltage is “3.0 V”, the capacity of the battery module is “0 Ah”; when the voltage is “3.1 V”, the capacity of the battery module is “10 Ah”; and when the voltage is “3.2 V”, the capacity of the battery module is “20 Ah”. Thus, in the “charge” sequence for the battery module number “M01”, the capacity-voltage profile data indicating the relationship between capacity and voltage at the time of charging is stored.

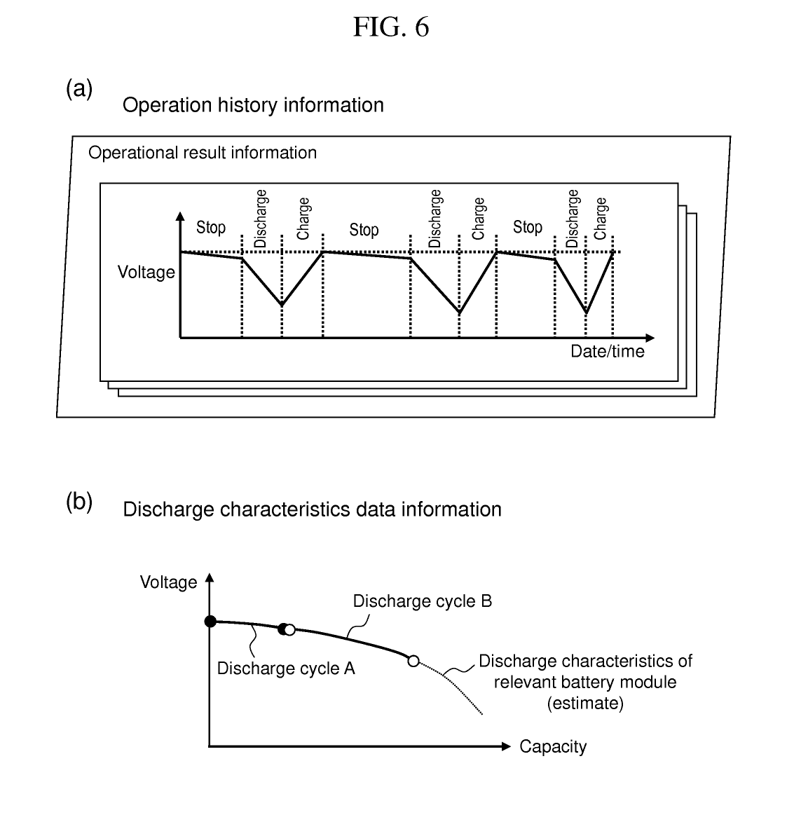

FIG. 6 illustrates the operational results information of each battery module. FIG. 6(a) illustrates the operation history information of each battery module recorded in the operational results database unit 131 of the maintenance management system 100. The horizontal axis shows time, and the vertical axis shows voltage. The operation history information is information associating a temporary change in voltage with the operation history (such as charging, discharging, and stop states). At least one piece of the operation history information is stored for the battery module as the object for management. Desirably, the operation history information includes all information following the start of battery module management. However, due to storage area capacity restrictions, generally past data is erased by refreshing. Thus, in reality, the relationship between voltage and temporary change with regard to the most recent operational results of each battery module is stored as the operation history information.

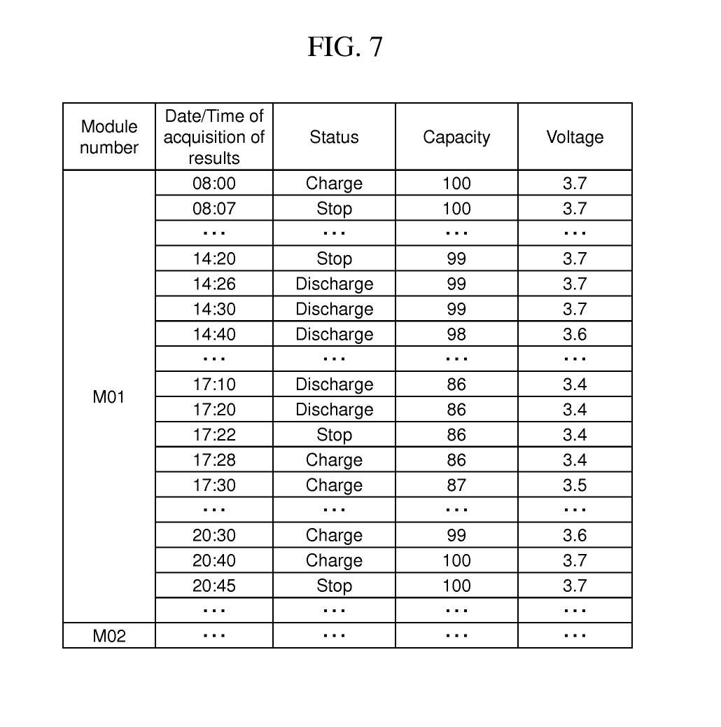

FIG. 7 illustrates an example of the operational results information recorded in the operational results database unit 131. The operational results information includes items of a battery module number identifying the battery module; results acquisition date/time; status; capacity; and voltage. The computation processing unit 120 acquires values of current and voltage that are input or output with respect to each battery module, determines whether the battery module is in a charged, discharged, or stop state, and stores the result of determination and accompanying information as the operational results information. The data records of the operational results information are created at 10 minute intervals, for example. The time of creation corresponds to the results acquisition date/time. As a corresponding status value, an identification code indicating a charge, a discharge, or a stop state is recorded.

The data records of the operational results information may be created only at the timing of sensing of a battery module status change. Obviously, the time of detection of status change is recorded as the results acquisition date/time.

The initial value of the capacity (100, for example) of the operational results information is the capacity of the battery system 200 charged at the time of product shipping. When the battery system 200 has been discharged, the discharge capacity (=discharge current×elapsed time) is subtracted from the capacity of the previous data record to determine the capacity of the data record that is recorded this time. On the other hand, when the battery system 200 has been charged, the charge capacity (=charge current×elapsed time) is added to the capacity of the previous data record to determine the capacity of the data record that is recorded this time.

A secondary battery such as the lithium ion battery suffers a large amount of self-discharge even in stop state. Thus, in the stop state status, past results are referred to in accordance with the current capacity, a self-discharge capacity multiplied by the stop time is subtracted from the capacity of the previous data record, and the computed value is set as the capacity of the data record recorded this time.

In the voltage of the operational results information, a current measurement value at the time noted in the results acquisition date/time is stored.

It may be a waste of store capacity to automatically record the data record with the status of stop state at 10 minute intervals. Thus, only the data record of the time at which the status switched to stop state and the data record of a predetermined measurement time immediately before switching to another status may be recorded, while omitting the recording of intervening data records.

As mentioned above, according to the present embodiment, it is necessary to leave a charge state history as operational results information for predicting a charge sequence. Thus, the discharge state history may also be omitted as in the stop state.

As described with reference to FIG. 4, when the charge characteristics data and the discharge characteristics data have substantially the same profile, a history of the operational results information of discharge state may also be left, so that, as needed, the capacity-voltage profile data of the charge characteristics data may be estimated from the operational results information of the latest discharge state.

FIG. 6(b) is a graph illustrating the discharge characteristics data information. The horizontal axis of the graph shows capacity, and the vertical axis shows voltage. During actual operation, not all of the battery modules may be completely discharged. Thus, in accordance with the discharge characteristics (estimate) indicated by the dotted line in the graph, the discharge characteristics are managed by the depth of discharge (DOD) starting from the voltage at the start of discharge. In FIG. 6(b), the difference between discharge cycles is indicated by black dots and white dots corresponding to the starting points and the end points of the cycles, respectively. The black dots correspond to a discharge cycle A, while the white dots correspond to a discharge cycle B. During data processing, an averaging process is performed.

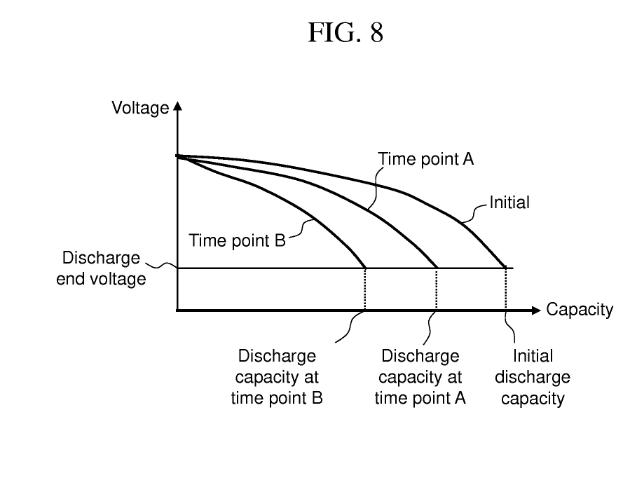

FIG. 8 illustrates how the discharge characteristics are changed as the battery module degrades. In the graph of FIG. 8, the horizontal axis shows capacity, and the vertical axis shows voltage. FIG. 8 shows, with respect to a certain battery module, profile data in the initial state (at the time of shipping); profile data at a point in time A after a predetermined period of use; and profile data at a point in time B after a predetermined period of further use. Each of the profile data is that of a case where discharge is started from the same voltage value and ended upon reaching the same discharge end voltage. It will be seen from FIG. 8 that the three cases of profile data differ from one another depending on the use time (i.e., in accordance with degradation). Thus, FIG. 8 shows that as the battery degrades, the amount of electricity that can be retained in the battery decreases.

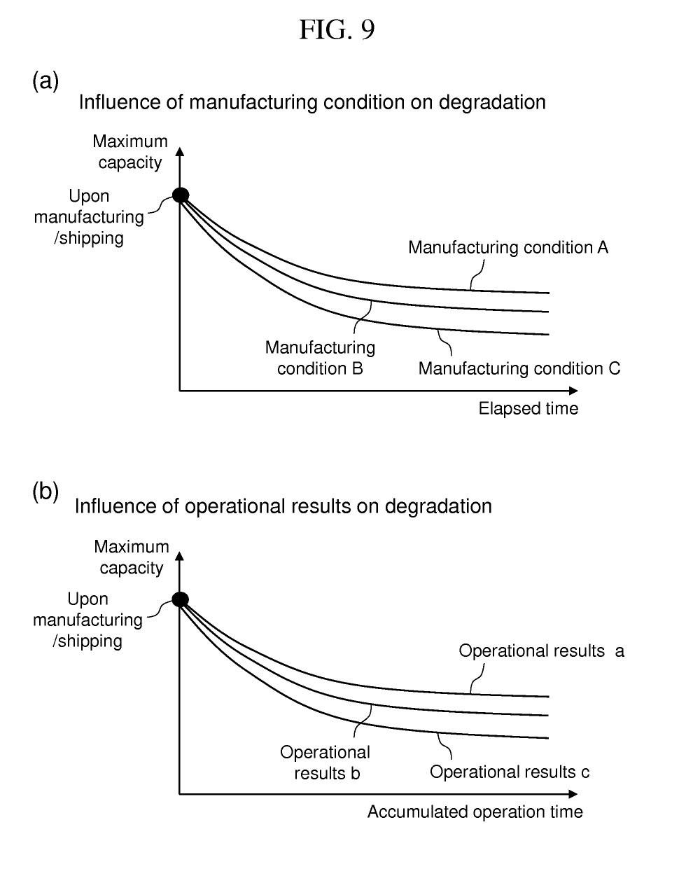

FIG. 9 illustrates the influence of manufacturing conditions and operational results on degradation over time of battery performance. FIG. 9(a) illustrates the influence of manufacturing conditions on battery degradation. FIG. 9(b) illustrates the influence of operational results on battery degradation. In each graph, the horizontal axis shows elapsed time, and the vertical axis shows capacity.

FIG. 9(a) compares the degradation over time of battery performance of three battery modules with different manufacturing conditions A, B, and C (such as temperature), where the discharge capacity of each battery module was measured, by the same method as in FIG. 8, after being let stand for the same length of time. It will be seen from the figure that the manufacturing conditions influence battery degradation.

FIG. 9(b) compares the degradation over time of battery performance of three battery modules in a case where the battery modules were used differently (i.e., when the operational results are different) and had the same accumulated operation time condition. It will be seen from the figure that the operational results influence battery degradation. From the measurement results of FIG. 8 and FIG. 9, it is predicted that the charge characteristics will have similar tendencies.

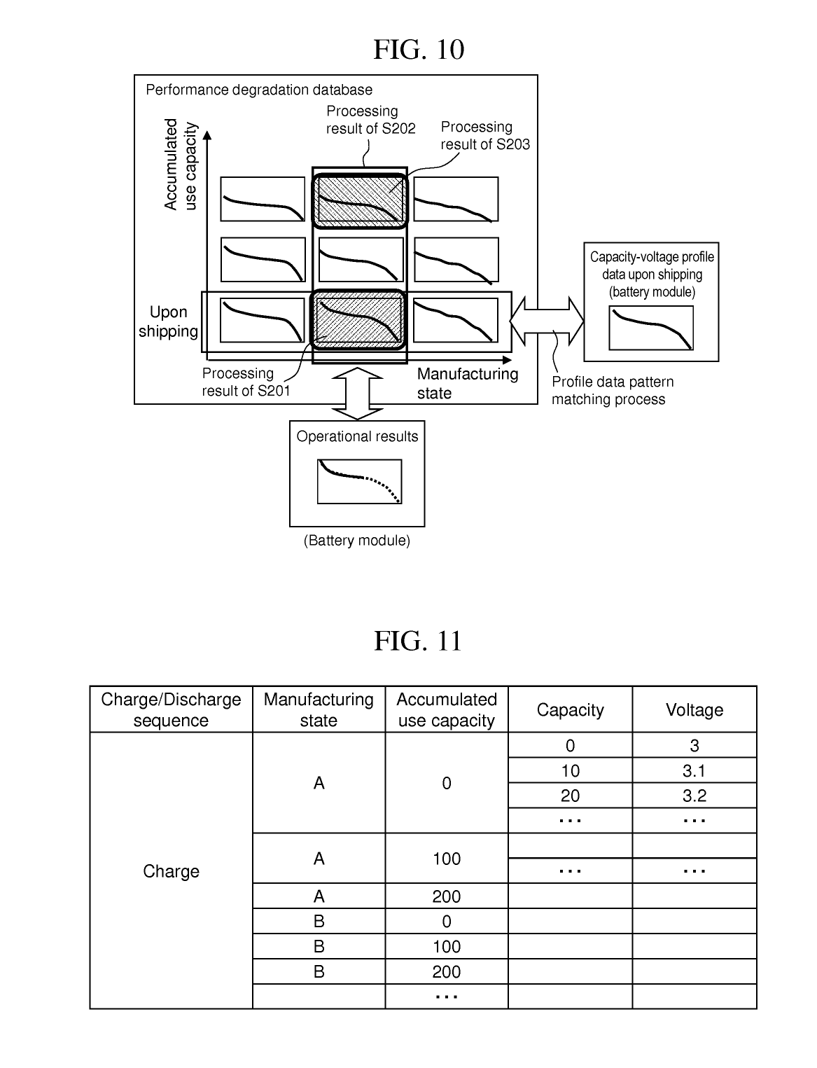

FIG. 10 schematically illustrates the performance degradation database 133. The horizontal axis shows an index such that, in recognition of the manufacturing conditions shown in FIG. 9(a), representative manufacturing conditions are arranged as separate manufacturing states. The vertical axis shows the accumulated use capacity in a case where the battery modules are repeatedly charged and discharged.

In the performance degradation database 133, with respect to a combination of manufacturing state and degradation state, capacity-voltage profile data is stored in advance as charge/discharge characteristics data.

The data correspond to the charge/discharge characteristics data of a battery module manufactured in each manufacturing state and measured at the time of shipping when the degradation state is zero, and to the charge/discharge characteristics data measured when the accumulated use capacity is a predetermined value.

FIG. 11 illustrates an example of the battery module inspection data registered in the performance degradation database 133. The performance degradation database 133 is created for each product type of the battery module. The performance degradation database 133 includes at least the data items of charge/discharge sequence, manufacturing state, accumulated use capacity, capacity, and voltage.

The manufacturing state is identified by the manufacturing condition (such as the temperature at the time of manufacture) of the battery module. The degradation state is indicated by the time for which the battery module manufactured in the corresponding manufacturing state is let stand. In the example of FIG. 11, when the battery module of a certain product type is manufactured in the manufacturing state “A” and let stand for the time “0” (i.e., immediately after manufacturing), the capacity of the battery module is “0 Ah” when the voltage is “3.0 V”; the capacity of the battery module is “10 Ah” when the voltage is “3.1 V”; and the capacity of the battery module is “20 Ah” when the voltage is “3.2 V”, for example. Such capacity-voltage profile data indicating the relationship between the capacity upon charging and voltage are stored upon elapsing of a predetermined let-stand time (such as at 100 hour intervals), the capacity and the voltage being associated with each other. The detailed contents of the capacity-voltage profile data will be described later.

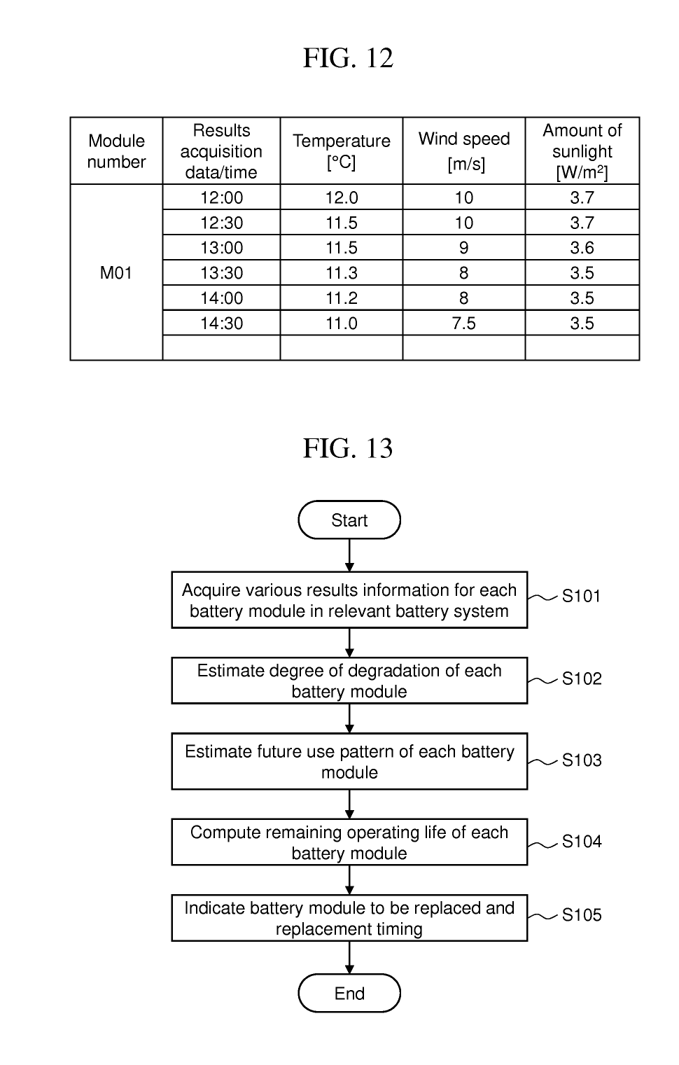

FIG. 12 illustrates an example of acquired data of environment information at the location of installation of the battery systems 200 registered in the environment results database 134. For example, environment results information such as temperature, humidity, wind speed (average wind speed, maximum wind speed), and amount of sunlight at the location of installation of the battery systems 200 is acquired at predetermined time intervals, an environment results information data record is created, and then the environment results information including the results acquisition date/time and the temperature, humidity, wind speed (average wind speed, maximum wind speed), the amount of sunlight and the like at the corresponding point in time is recorded in each data record. Each item of the environment results information is associated with a module number.

### [Battery Module Replacement Timing Computation Process]

Referring to FIG. 13, the contents of a process executed when the replacement timing for each of the battery modules constituting the battery system is computed by the computation processing unit 120 of the present embodiment will be described.

### (Step S101)

First, the computation processing unit 120, with respect to each battery module of the battery systems 200, reads various results data from the database unit 130.

For example, the computation processing unit 120 reads from the operational results database 131 (FIG. 7) the capacity-voltage profile data concerning the most recent charge process corresponding to a battery module number, and past operational results data.

If the capacity-voltage profile data concerning the most recent charge process is that of a process by which only a small portion of the entire capacity was charged, an older operation history may be incorporated to the object of search so that the capacity-voltage profile data of a charge process with greater charge capacity may be read.

When the discharge capacity in the most recent discharge process is large, the relationship between capacity and voltage in the capacity-voltage profile data may be inverted with respect to left and right, and the computed capacity-voltage profile data may be substituted as the capacity-voltage profile data concerning the charge process.

The computation processing unit 120 reads from the manufacturing inspection results database 132 (FIG. 5) the operational results data corresponding to the battery module number and the capacity-voltage profile data at the time of shipping, for example.

The computation processing unit 120 also reads from the environment results database 134 (FIG. 12) the environment results data corresponding to the battery module number, for example.

The computation processing unit 120 also reads from the check plan database 135 check plan data corresponding to the battery system number.

### (Step S102)

The computation processing unit 120 (specifically, the degradation degree estimation processing unit 121) performs a process of collating the capacity-voltage profile data at the time of shipping acquired in step S101 and the most recent capacity-voltage profile data with the capacity-voltage profile data stored in the performance degradation database 133 (FIG. 11) to estimate the degradation state (degradation degree) of the relevant battery module.

### (Step S103)

The computation processing unit 120 (specifically, the use pattern estimation processing unit 122) creates a past use pattern from the past operational results data acquired in step S101 and the environment results data to estimate a future use pattern for each battery module. Specifically, based on the past use pattern, the future use capacity of the battery module is estimated in terms of a distribution having a use capacity average value and a standard deviation at elapsed time intervals.

### (Step S104)

The computation processing unit 120 (specifically, the remaining operating life computation processing unit 123), using the degradation degree of the battery module computed in step S102 and degradation transition data of the corresponding battery module with respect to the accumulated use capacity, and the future use pattern of the relevant battery module computed in step S103, computes a distribution having an average value of the maximum capacity and a standard deviation at elapsed time intervals of the relevant battery module.

### (Step S105)

The computation processing unit 120 (specifically, the replacement timing indication processing unit 124), using the check plan data acquired in step S101 and the remaining operating life data of the relevant battery module computed in step S103, designates a battery module to be replaced at each time of checking. If it is computed that the necessary capacity cannot be ensured before the next time of checking, an indication for modifying the check timing is issued.

### [Detailed Operation of Step S102]

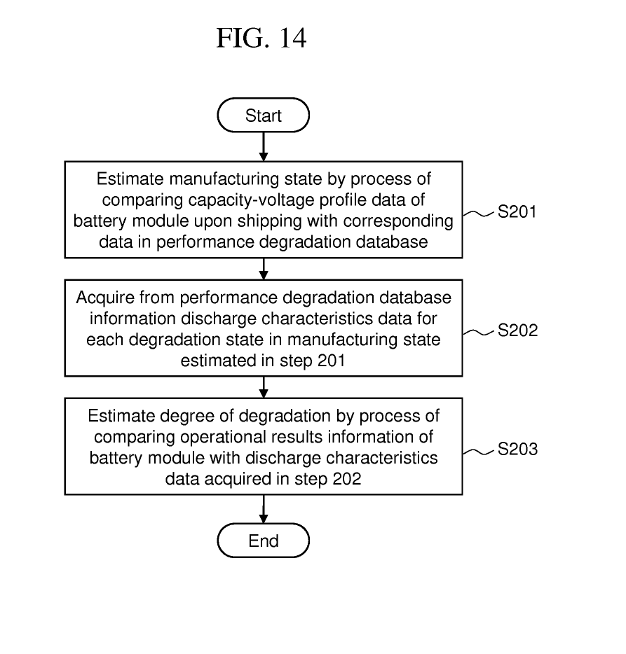

FIG. 14 illustrates the details of the process operation performed in step S102.

### (Step S201)

The degradation degree estimation processing unit 121 compares the capacity-voltage profile data at the time of shipping acquired in step S101 with the corresponding data stored in the performance degradation database 133 to estimate corresponding data closest to the manufacturing state of the battery module as the object for processing. In FIG. 10, one profile data with the lead line noting “Process result of S201” and enclosed by a bold frame is identified.

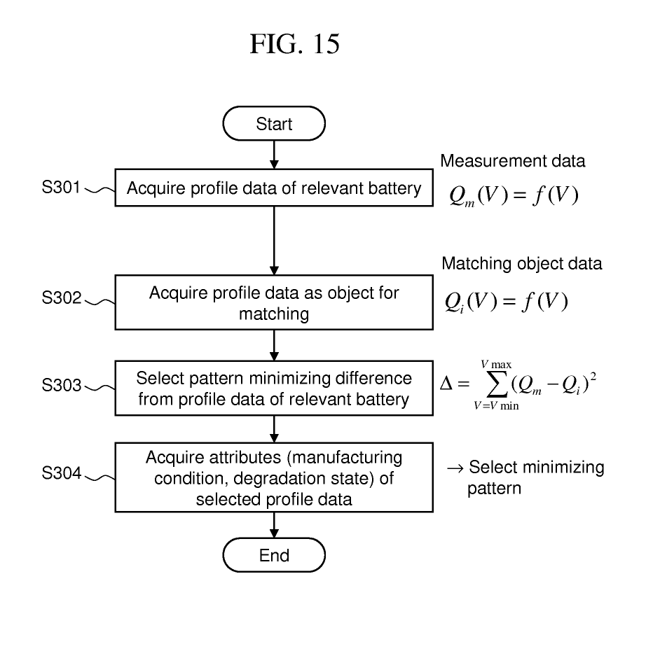

For the estimating process here, the pattern matching method described in FIG. 15 is used, for example. First, the degradation degree estimation processing unit 121 acquires the capacity-voltage profile data measured from the relevant battery module (step S301).

Measurement data Qₘ(V) of the battery module is expressed by the following expression.

Qₘ(V)=f(v) (Expression 1)

where f(V) is a function of the voltage V.

Then, the degradation degree estimation processing unit 121 acquires the capacity-voltage profile data as the matching object from the performance degradation database 133 (step S302).

The matching object data Qᵢ(V) is expressed by the following expression:

Qᵢ(V)=f(v) (Expression 2)

where f(V) is a function of voltage V.

The degradation degree estimation processing unit 121 then calculates a difference Δ between the measurement data Qₘ(V) and the matching object data Qⁱ(V) according to the following expression.

$$Δ = {\sum }_{V = {V}_{m i n}}^{{V}_{m ax}} {( {Q}_{m} - {Q}_{i} )}^{2} \qquad ( Expression 3 )$$

The degradation degree estimation processing unit 121 calculates the difference Δ from the measurement data Qₘ(V) with respect to all of the matching object data Qᵢ(V), and selects its minimum value.

Thereafter, the degradation degree estimation processing unit 121 acquires attributes (manufacturing state, degradation state) of the capacity-voltage profile data selected in step S303 (step S304).

### (Step S202)

The degradation degree estimation processing unit 121 acquires the capacity-voltage profile data of each degradation state registered with respect to the manufacturing state estimated in step S201. Specifically, the degradation degree estimation processing unit 121 acquires all of the capacity-voltage profile data arranged in the same vertical column as the capacity-voltage profile data indicated by “Process result of S201” in FIG. 10. In FIG. 10, the three profile data included in the frame attached with the lead line noted “Process result of S202” are acquired.

### (Step S203)

The degradation degree estimation processing unit 121 compares the capacity-voltage profile data representing the operational results information of the battery module as the current charge object that has been read in step S101 with the capacity-voltage profile data of each degradation state acquired in step S202 to estimate the corresponding data closest to the degradation state of the relevant battery module. In FIG. 10, one profile data enclosed by a bold frame with the lead line noting “Process result of S203” is identified.

In this estimating process too, the capacity-voltage profile data corresponding to the degradation state such that the difference Δ is minimized is selected using the pattern matching method illustrated in FIG. 15. Further, the degradation degree estimation processing unit 121, based on the capacity-voltage profile data corresponding to the selected degradation state, estimates the degradation degree of the battery module as the current object for charging.

The voltage range (indicated by solid line in a bottom frame of FIG. 10) of the capacity-voltage profile data representing the operational results information as the object for the pattern matching process is normally not the same as the voltage range of the capacity-voltage profile data stored in the performance degradation database. Thus, the pattern matching process computes a difference in a common voltage range of both of the capacity-voltage profile data.

From the above reasons, when the capacity-voltage profile data representing the operational results information is selected, the accuracy of the pattern matching process can be increased by selecting the operational results information having a voltage range close to the voltage range of the capacity-voltage profile data stored in the performance degradation database as much as possible.

### [Detailed Operation of Step S103: 1]

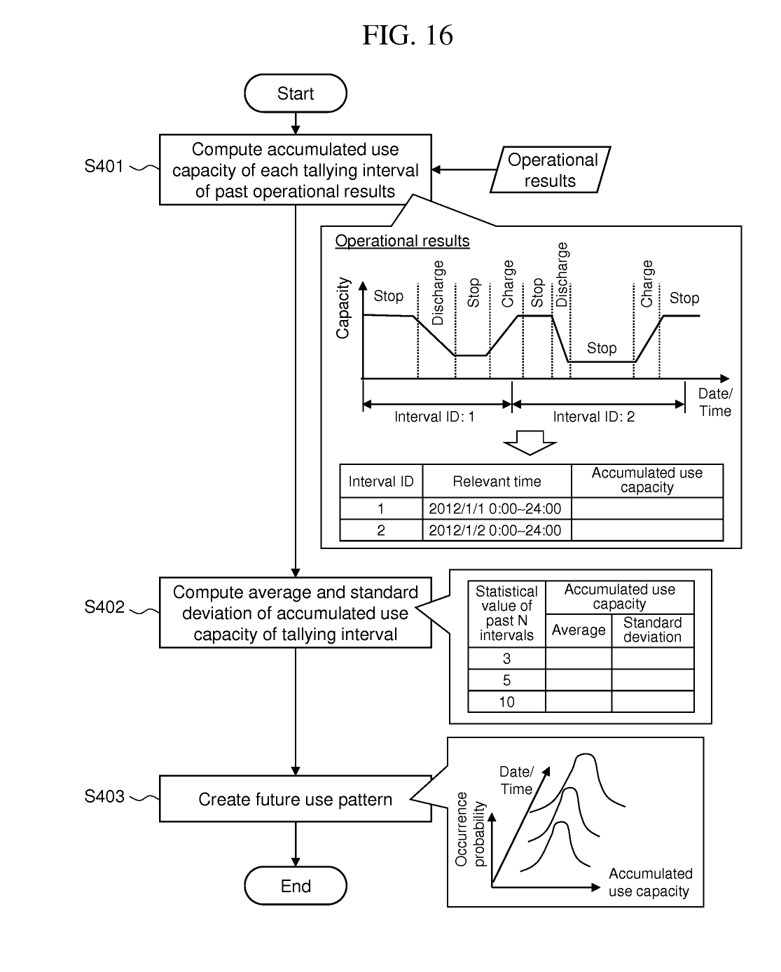

FIG. 16 illustrates the details of the process operation performed in step S103. Namely, a method of estimating the future use pattern will be described.

### (Step S401)

The use pattern estimation processing unit 122 computes the accumulated use capacity for each tallying interval from the operational results data of the relevant battery module that has been acquired in step S101 for each of predetermined tallying intervals that are set in advance.

### (Step S402)

The use pattern estimation processing unit 122 computes an average value and a standard deviation of the accumulated use capacity between the tallying intervals from the accumulated use capacity for each of the tallying intervals computed in step S301. For example, the use pattern estimation processing unit 122, with respect to the accumulated use capacity in the past N tallying intervals, computes its average value and standard deviation. The value of N is set such that the object intervals are from several days to several months.

### (Step 403)

The use pattern estimation processing unit 122, based on the result of computation of the average and standard deviation of the past accumulated use capacity between the tallying intervals computed in step S302, estimates a distribution of the accumulated use capacity for each of the future tallying intervals with respect to the relevant battery module. For example, the distribution of the accumulated use capacity for the coming whole day is created from the average and standard deviation of the accumulated use capacity for the past seven days. For the subsequent distribution of the accumulated use capacity, the average and standard deviation of the accumulated use capacity including days even before the past seven days are computed. Thus, when the distribution of the future accumulated use capacity is estimated, the range of the past results is increased so as to reflect the future uncertainty in the distribution.

### [Detailed Operation of Step S103: 2]

Another process operation preferable for step S103 will be described. Specifically, a method of using past operational results data and environment results data for estimating the future use pattern will be described. FIG. 17 illustrates the details of the process operation performed in step S103.

### (Step S501)

The use pattern estimation processing unit 122 computes the accumulated use capacity for each tallying interval from the operational results data of the relevant battery module acquired in step S101 for each of the predetermined tallying intervals set in advance. This process is the same as step S401.

### (Step S502)

The use pattern estimation processing unit 122 computes an average value of the environment results data for each tallying interval from the environment results data of the relevant battery system acquired in step S101, for each of the predetermined tallying intervals set in advance. It is assumed that, as the environment results data, the temperature, humidity, wind speed (average wind speed, maximum wind speed), the amount of sunlight and the like at the location of installation of the battery system are regularly measured.

### (Step S503)

The use pattern estimation processing unit 122, using the accumulated use capacity for each tallying interval computed in step S501 and the average value data of the environment results for each tallying interval computed in step S502, creates a mathematical model representing the relationship between the accumulated use capacity and the environment results. For example, the use pattern estimation processing unit 122 creates the mathematical expression of the relationship between the environment results data and the accumulated use capacity by performing multiple regression computation using the accumulated use capacity as the objective variable and each of the environment results data items as the explanatory variable.

### (Step S504)

The use pattern estimation processing unit 122 computes a change over time of the environment results, using the past environment results data. For example, for the change over time in one day, a temporary change in each day of the week is calculated on a weekly basis by computing an average value and a standard deviation of each tallying interval. The change per day on a weekly basis is calculated by computing an average value and a standard deviation of each day of the week on a monthly basis.

### (Step S505)

The use pattern estimation processing unit 122 substitutes the change over time of the average and standard deviation of the environment results data computed in step S504 into the mathematical expression model created in step S503 representing the relationship between the accumulated use capacity and the environment results, and computes a use pattern distribution corresponding to the change over time of the environment results.

### [Detailed Operation of Step S104]

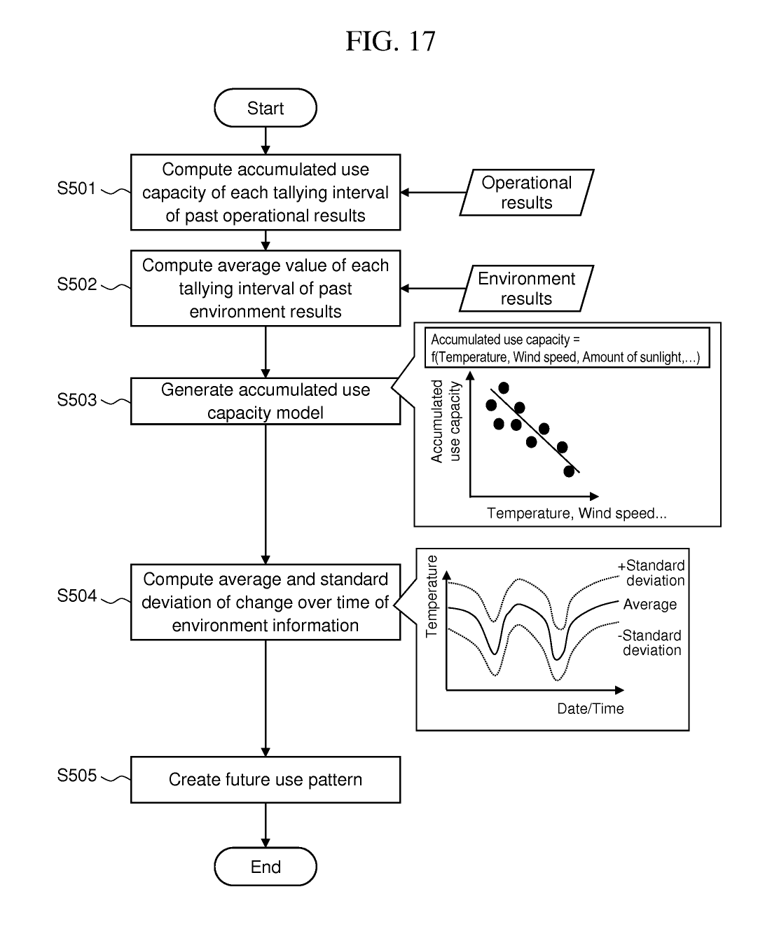

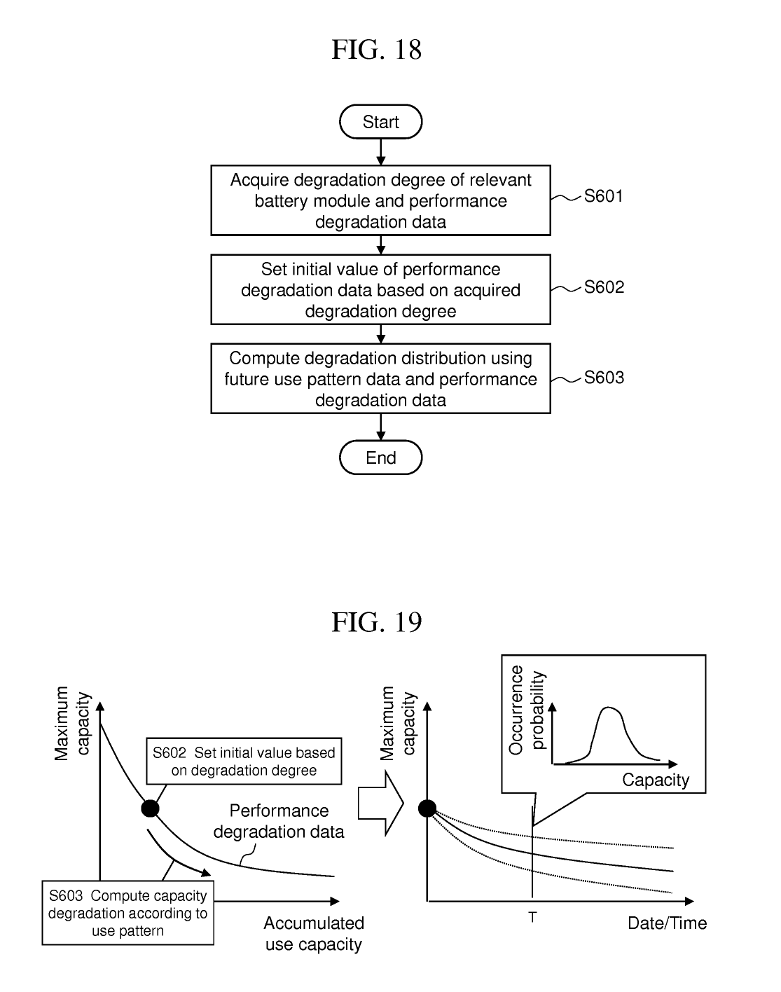

FIG. 18 illustrates the details of the process operation performed in step S104. Namely, the details of the process of computing the remaining operating life of a battery module will be described.

### (Step S601)

The remaining operating life computation processing unit 123 acquires the performance degradation data acquired in step S101, the degradation degree of the relevant battery module computed in step S203, and the performance degradation data used for the computation.

### (Step S602)

The remaining operating life computation processing unit 123, based on the information acquired in step S601, sets an initial value indicating the current point state of the performance degradation data indicating the relationship between the accumulated use capacity of the relevant battery module and the capacity.

### (Step S603)

The remaining operating life computation processing unit 123 substitutes, into the performance degradation change data with respect to the use capacity from the current point of the relevant battery module acquired in step S602, the distribution data of the relevant battery module use pattern computed in step S403 or step S505, to compute a distribution (average value and standard deviation) of transition of the performance degradation with respect to the future change over time of the relevant battery module.

FIG. 19 illustrates the results of computation of the remaining operating life. As described above, in step S601, the performance degradation data indicating the relationship of the performance degradation with respect to the accumulated use capacity of the relevant battery module is acquired. In step S602, based on the degradation degree computed in step S203 on the basis of the acquired performance degradation data, the initial value indicating the current point in the performance degradation data is set. In FIG. 19, the initial value is denoted by a black dot. The graph on the left shows the accumulated use capacity on the horizontal axis and the maximum capacity on the vertical axis. The graph on the right shows the date on the horizontal axis and the maximum capacity on the vertical axis.

Thereafter, in step S603, the transition of the future use capacity is substituted into the relationship between the accumulated use capacity and capacity degradation change following the initial value of the performance degradation data, so as to compute the distribution of transition of the performance degradation with respect to the future change over time. For example, the graph on the right on FIG. 19 is displayed on a display as a screen presenting the remaining operating life. In the figure, the profile shown by a solid line is the average predicted value, and the profile shown by dotted lines are profiles having a difference of ±3σ with respect to the average value.

### [Detailed Operation of Step S105]

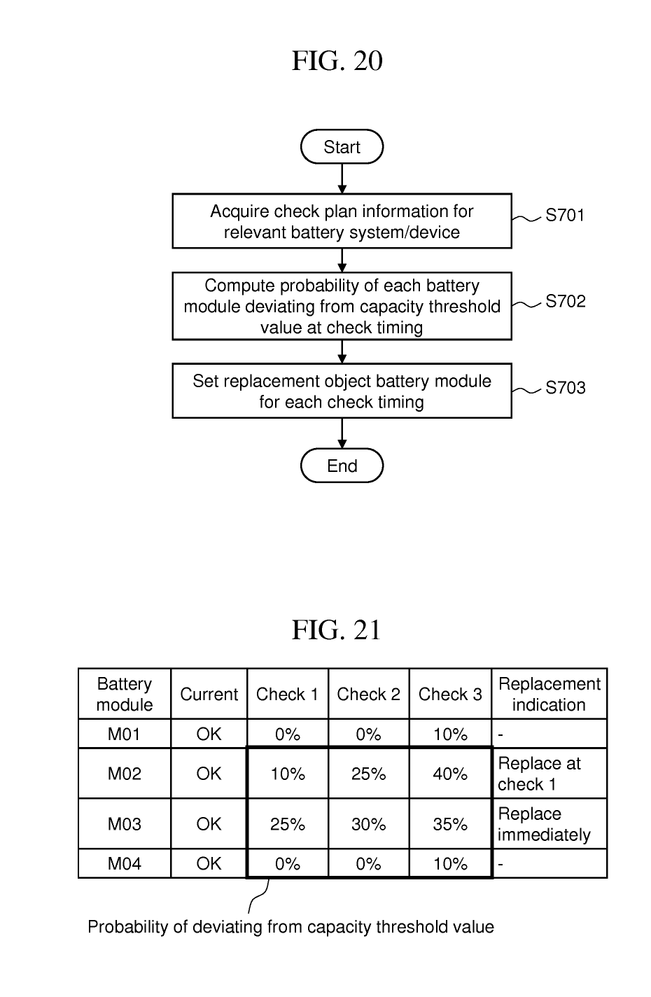

FIG. 20 illustrates the details of the process operation performed in step S105. Namely, the details of the replacement timing indication process will be described.

### (Step S701)

The replacement timing indication processing unit 124 acquires the check plan information for the relevant battery system and device.

### (Step S702)

The replacement timing indication processing unit 124, using the computed result of the remaining operating life for each battery module computed in step S603, computes the probability of the capacity of each battery module becoming lower than (deviating from) a threshold value with respect to each check point in time acquired in step S701.

### (Step S703)

The replacement timing indication processing unit 124, with respect to the battery module of which the probability computed in step S702 exceeds the allowable value, indicates that the administrator should replace the battery module at a check timing before the allowable value is exceeded. On the other hand, if the probability of deviating the capacity threshold value at the next check timing exceeds the allowable value, information “Replace immediately” is output. The indication may involve an alert sound, a warning lamp, or voice, or a display of characters or illustrations and the like on an administrator screen.

FIG. 21 illustrates an example of the result of computation of the replacement timing for each battery module. FIG. 21 per se may be displayed on the administrator screen. The data table shown in FIG. 21 includes the data items of battery module, its current operation status, check plan 1, check plan 2, check plan 3, and replacement indication. The information is stored for each battery module.

In the columns for check plans 1 to 3, the probability of the capacity of the battery module deviating from the threshold value at the time of execution of each check is displayed. For example, when the probability of the capacity deviating from the threshold value has an allowable value of 20%, the battery module MO2 exceeds the allowable value at the point in time of the check timing 2. Thus, the “check plan 1” which is two timings earlier is identified as the replacement timing, and an indication message “Replace at check 1” is displayed in the replacement indication column. The battery module MO3 already exceeds the allowable value at the point in time of the next check plan 1. Thus, in the replacement indication column corresponding to the battery module MO3, “Replace immediately” is displayed. The battery modules MO1 and MO4 do not exceed the allowable value within the three most-recent check plans, so that no replacement indication is issued.

In FIG. 21, the check timings are set in advance, and the probability computed for the three nearest future check timings and the allowable value are compared. However, a method may be used whereby simply the timing exceeding an allowable value is notified.

### CONCLUSION

By using the maintenance management system 100 according to the present embodiment, the replacement timing can be determined for each battery module by considering the manufacturing variation or operational results variation of each battery module, and an indication can be issued. Based on the relationship with the check plan that is expected for a battery system, the replacement timing indication can be issued. Thus, battery system maintenance can be managed efficiently, whereby the operating ratio of the battery system as a whole can be increased.

### OTHER EMBODIMENTS

The present invention is not limited to the above implementation examples and may include various modifications. The foregoing implementation examples have been described for the purpose of facilitating an understanding of the present invention, and the present invention is not limited to an implementation example having all of the described configurations. A part of one implementation example may be replaced by the configuration of another implementation example, or the configuration of the other implementation example may be incorporated into the configuration of the one implementation example. With regard to a part of the configuration of each implementation example, addition, deletion, or substitution of other configurations may be made.

Some or all of the configurations, functions, processing units, process means and the like may be realized by an integrated circuit or other hardware. The configurations, functions and the like may be realized by a processor interpreting and executing a program configured to realize the respective functions. Namely, the configurations, functions and the like may be realized by software. The program for realizing the functions and information about tables, files and the like may be stored in a storage device such as a memory, a hard disk, or a solid state drive (SSD), or a storage medium such as an IC card, an SD card, or a DVD.

The control lines and information lines indicate only those considered necessary for description and may not necessarily represent all of the control inlines or information lines required in a product. It may be considered that almost all configurations are mutual connected in reality.

### REFERENCE SIGNS LIST

100 Maintenance management system
200 Battery system
300 Device
110 Data input/output processing unit
120 Computation processing unit
121 Degradation degree estimation processing unit
122 Use pattern estimation processing unit
123 Remaining operating life computation processing unit
124 Replacement timing indication processing unit
130 Database unit
131 Operational results database
132 Manufacturing inspection results database
133 Performance degradation database
134 Environment results database
135 Check plan database
201 Battery module

1. A battery system maintenance management system comprising:
a data input/output processing unit;
a database unit;
a degradation degree estimation unit that estimates a degradation degree of each battery module of a battery system by collating capacity-voltage profile data of the battery module according to manufacturing state and degradation state, capacity-voltage profile data at the time of shipping of the battery module, and most recent capacity-voltage profile data of the battery module;
a use pattern estimation unit that estimates a future use pattern based on past charge/discharge results data of the battery module;
a remaining operating life computation unit that computes remaining operating life based on the degradation degree, the use pattern of the battery module, and characteristics degradation data; and
a replacement timing indication unit that indicates a replacement timing of the battery module based on the remaining operating life computed for the battery module.

2. The battery system maintenance management system according to claim 1, characterized in that the replacement timing indication unit computes the probability of the remaining operating life becoming equal to or smaller than a threshold value at a check point in time, and determines the replacement timing of the battery module based on a result of the computation.

3. The battery system maintenance management system according to claim 2, characterized in that the replacement timing indication unit displays the replacement timing of the battery module in terms of a relationship between the check timing and the computed probability.

4. The battery system maintenance management system according to claim 3, characterized in that the replacement timing indication unit displays information about the replacement timing of the battery module on one and the same screen.

5. The battery system maintenance management system according to claim 1, characterized in that the replacement timing indication unit displays the remaining operating life computed for each battery module in the form of a distribution graph having a predetermined width.

6. The battery system maintenance management system according to claim 1, characterized in that the use pattern estimation unit creates a model of a relationship between an accumulated use capacity at certain time intervals and an environment results at a location of installation of the battery module based on the past charge/discharge results data and the environment results, and estimates the future use pattern based on the model.

7. The battery system maintenance management system according to claim 6, characterized in that the environment results is one of a temperature, a humidity, an average wind speed, a maximum wind speed, and an amount of sunlight, or an arbitrary combination thereof.

8. A battery system maintenance management method comprising:
a process of a computation processing unit that manages maintenance of a battery system estimating a degradation degree of each battery module of a battery system by collating capacity-voltage profile data of the battery module according to manufacturing state and degradation state, capacity-voltage profile data at the time of shipping of the battery module, and most recent capacity-voltage profile data of the battery module;
a process of the computation processing unit estimating a future use pattern based on past charge/discharge results data of the battery module;
a process of computing remaining operating life based on the degradation degree, the use pattern of the battery module, and characteristics degradation data; and
a process of indicating a replacement timing of the battery module based on the remaining operating life computed for the battery module.

9. The battery system maintenance management method according to claim 8, characterized by a process of computing the probability of the remaining operating life becoming equal to or smaller than a threshold value at a check point in time, and determining the replacement timing of the battery module based on a result of the computation.

10. The battery system maintenance management method according to claim 9, characterized by a process of displaying the replacement timing of the battery module in terms of a relationship between the check timing and the computed probability.

11. The battery system maintenance management method according to claim 10, characterized in that, together with the relationship, information about the replacement timing of the battery module is displayed on one and the same screen.

12. The battery system maintenance management method according to claim 8, characterized by a process of displaying the remaining operating life computed for each battery module in the form of a distribution graph having a predetermined width.

13. The battery system maintenance management method according to claim 8, characterized by a process of creating a model of a relationship between an accumulated use capacity at certain time intervals and an environment results at a location of installation of the battery module based on the past charge/discharge results data and the environment results, and estimating the future use pattern based on the model.
